(19) United States
(12) Patent Application Publication
(10) Pub. No.: US 2004/0229470 A1
(43) Pub. Date: Nov. 18, 2004

(54) Method for etching an aluminum layer using an amorphous carbon mask

(75) Inventors: Ying Rui, Sunnyvale, CA (US); Chun Yan, San Jose, CA (US); Wai-Fan Yau, Los Altos, CA (US)

Correspondence Address: MOSER, PATTERSON & SHERIDAN, LLP, APPLIED MATERIALS INC, 595 SHREWSBURY AVE, SUITE 100, SHREWSBURY, NJ, 07702, US

(73) Assignee: Applied Materials, Inc.

(21) Appl. No.: 10/438,638

(22) Filed: May 14, 2003

(51) Int. Cl. H01L 21/302; H01L 21/461

(52) U.S. Cl. 438/710

(57) ABSTRACT

A method of etching an aluminum (Al) layer comprising forming an α-carbon (i.e., inorganic amorphous carbon) mask, plasma etching the aluminum layer using the α-carbon mask, and plasma stripping the α-carbon mask. In one embodiment, the method is performed on a single processing platform as an integrated solution for etching aluminum.

### BACKGROUND OF THE INVENTION

1. Field of the Invention

The present invention generally relates to a method for fabricating devices on semiconductor substrates. More specifically, the present invention relates to a method for performing an etch process in a semiconductor substrate processing system.

2. Description of the Related Art

As is known in the art, aluminum (Al) has long been the material of choice for back-end-of-the-line (BEOL) metallization. One approach for etching aluminum is to use a photoresist mask that defines an individual structure, such as, e.g., a conductive line. Portions of an aluminum layer that are not protected by the photoresist mask are selectively removed using an etch process, while the remaining protected portions of the layer form the structure.

With shrinking device geometries, thickness of the photoresist mask also decreases to satisfy requirements of optical lithography used to pattern the photoresist mask. Etch chemistry for aluminum is based on chlorine (Cl₂) and known in the art for low selectivity, such as about 3:1, to aluminum versus photoresist. Such low selectivity requires use of photoresist masks having a thickness of about 5000 Angstroms or greater. Thinner photoresist mask can be insufficient to protect the underlying aluminum layer during the entire etch process, as well as provide accurate patterning of the aluminum layer. At the same time, in advanced IC devices having high circuit density, the thickness of interconnecting conductive lines tends to increase to compensate for a decreasing width of the conductive lines. As such, the photoresist mask becomes a limiting factor in fabrication of the IC devices.

During etching aluminum using the photoresist mask, a chlorine-containing polymeric residue forms on sidewalls of the etched structure as a result of a reaction between chlorine and photoresist. Upon exposure to moisture, such residue may give rise to aluminum corrosion. The corrosion in aluminum layers is caused by hydrogen chloride (HCl) that is formed by the reaction of water vapors (H₂O) with chlorine components in the etchant gas, photoresist, and by-products of the etch process.

An alternative approach to using a photoresist mask has been the use of a hard mask. Different materials have been suggested for the hard mask, e.g., silicon dioxide (SiO₂), silicon nitride (Si₃N₄), and the like. Use of the hard mask requires performing additional multi-step process sequences, comprising steps of forming a first supplemental photoresist mask to define the hard mask on the aluminum layer and a second supplemental photoresist mask used to facilitate stripping of the hard mask after the aluminum etch process. Further, remaining post-strip traces of dielectric material of the hard mask may be a contaminant in the processes subsequent to the metallization step.

Therefore, there is a need in the art for a method of etching an aluminum layer during fabrication of IC devices.

### SUMMARY OF THE INVENTION

The present invention is a method of etching an aluminum (Al) layer formed upon a semiconductor substrate. The method comprises forming an α-carbon mask (i.e., inorganic amorphous carbon mask) to define a structure such as a conductive line and the like in the aluminum layer, etching aluminum using the α-carbon mask, and removing the α-carbon mask when the structure is formed. In one embodiment, the method is performed on a single processing platform as an integrated solution for etching aluminum.

### BRIEF DESCRIPTION OF THE DRAWINGS

The teachings of the present invention can be readily understood by considering the following detailed description in conjunction with the accompanying drawings, in which:

FIG. 1 depicts a flow diagram of a method of etching an aluminum layer in accordance with the present invention;

FIGS. 2A-2J together depict a sequence of schematic, cross-sectional views of a substrate having a conductive line being formed in accordance with the method of FIG. 1;

FIG. 3 depicts a schematic diagram of an exemplary plasma processing apparatus of the kind used in performing portions of the method of FIG. 1; and

FIG. 4 depicts a schematic, plan view of a processing platform used to perform the method of the present invention.

To facilitate understanding, identical reference numerals have been used, where possible, to designate identical elements that are common to the figures.

It is to be noted, however, that the appended drawings illustrate only exemplary embodiments of this invention and are therefore not to be considered limiting of its scope, for the invention may admit to other equally effective embodiments.

### DETAILED DESCRIPTION

The present invention is a method of etching an aluminum (Al) layer formed on a semiconductor substrate, e.g., a silicon (Si) wafer. The method comprises forming an α-carbon mask (i.e., inorganic amorphous carbon mask) on the aluminum layer to define a structure (e.g., a conductive line and the like), plasma etching the aluminum layer using the α-carbon mask as an etch mask, and removing the α-carbon mask using a plasma strip process after the conductive line has been formed. The invention is generally applicable to applications where a width of an aluminum conductive line is about 100 to 180 nm or less.

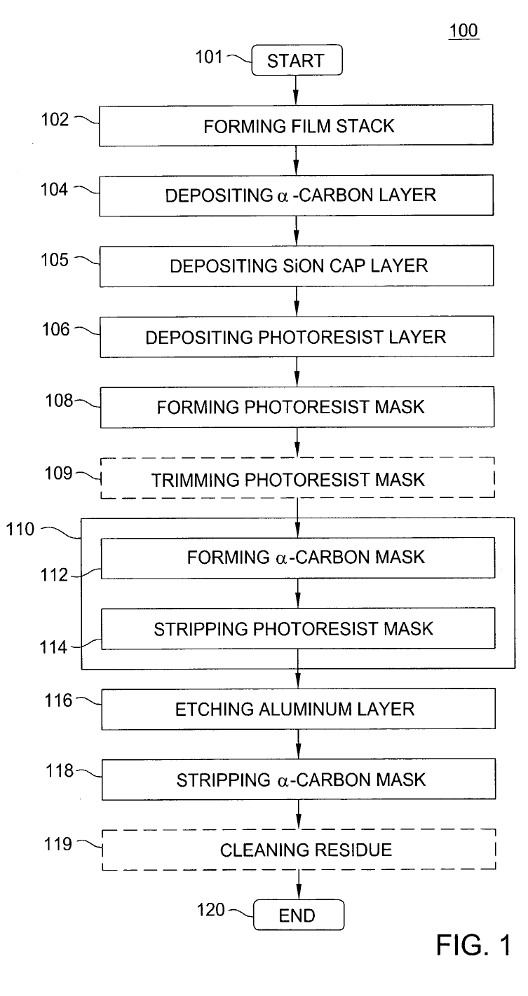

FIG. 1 depicts a flow diagram of a method of etching an aluminum layer in accordance with the present invention as a method 100. The method 100 comprises processes that are illustratively performed upon the aluminum layer during fabrication of a conductive line.

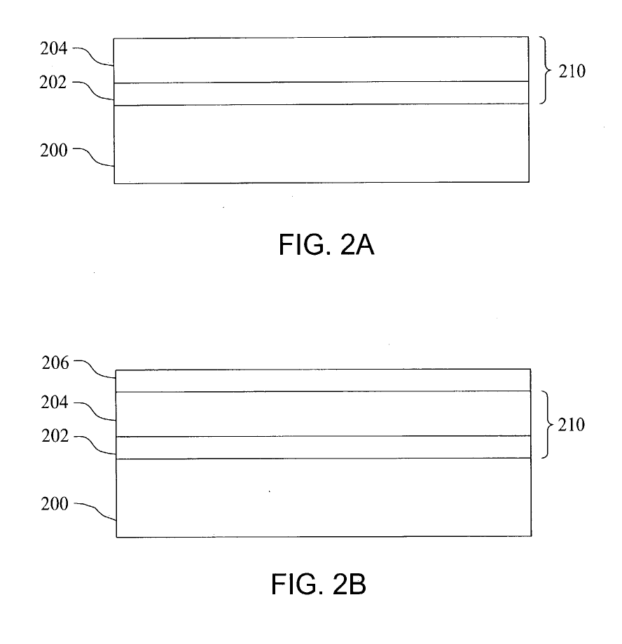

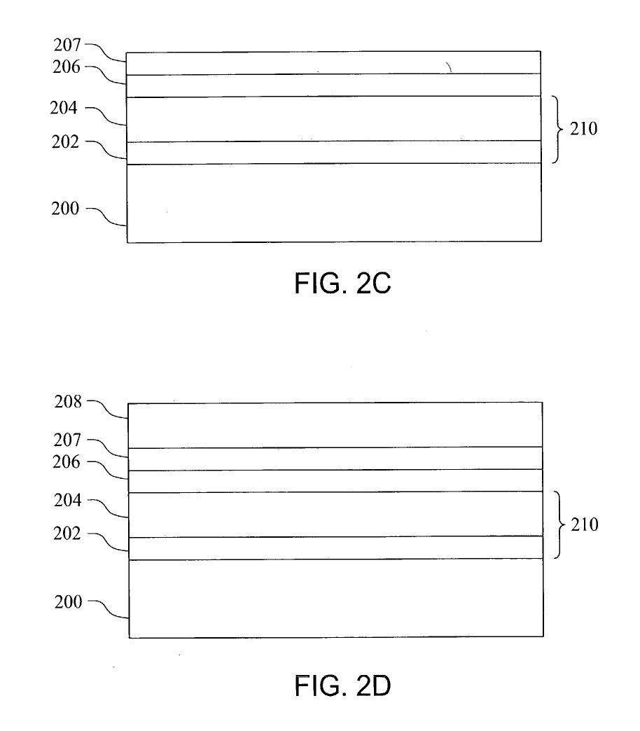

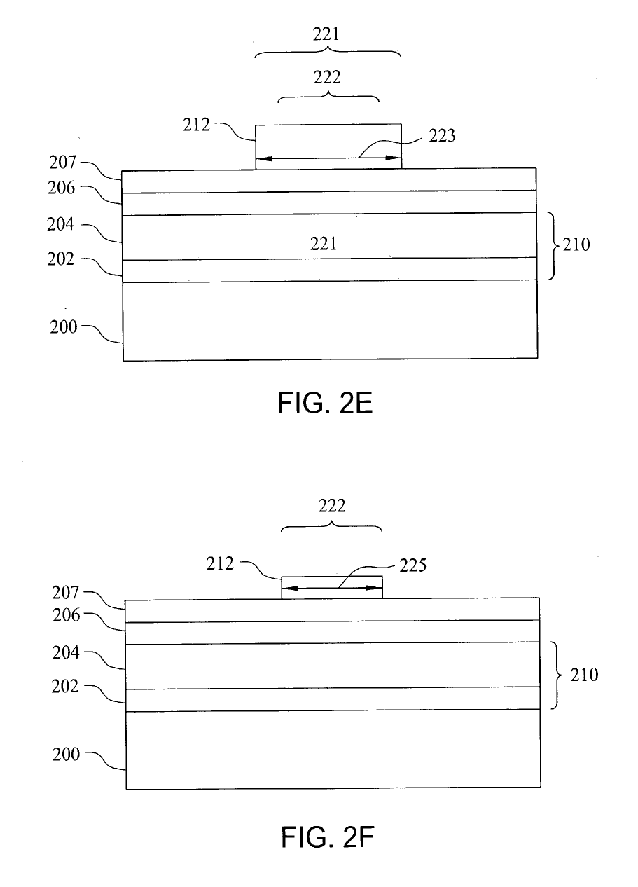

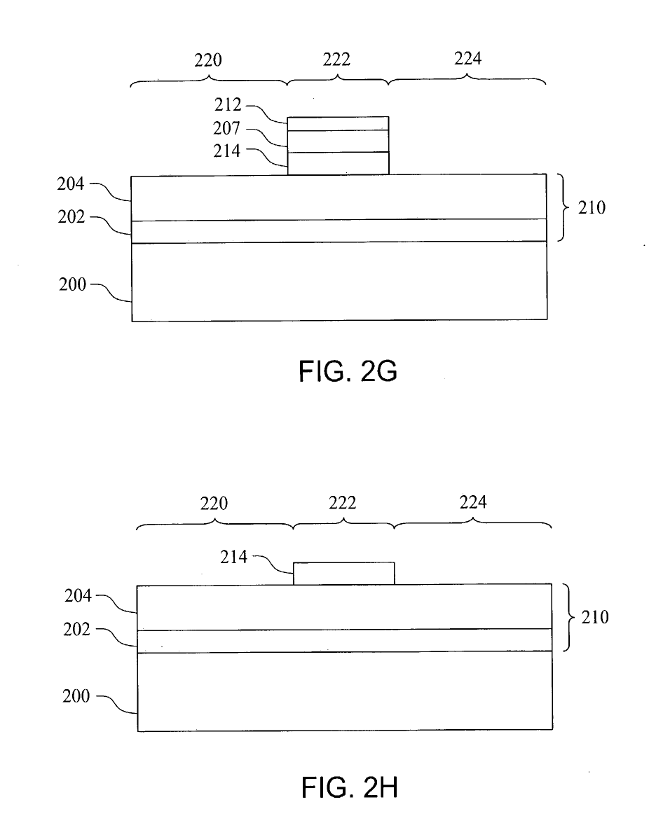

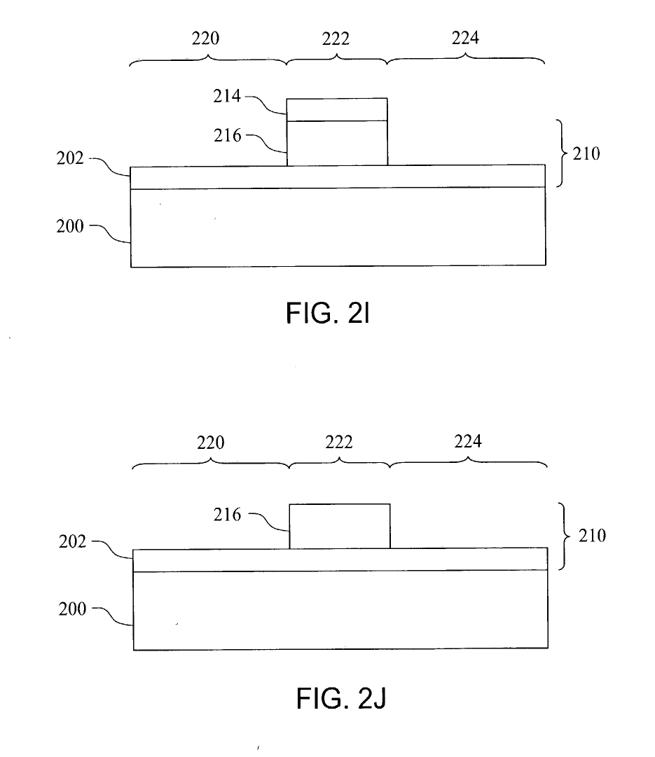

FIGS. 2A-2J together depict a sequence of schematic, cross-sectional views of a substrate having a conductive line being formed in accordance with the method 100 of FIG. 1. The cross-sectional views in FIGS. 2A-2J relate to individual process steps used to form the conductive line. Sub-processes such as lithographic processes (e.g., exposure and development of photoresist, and the like) among others are well known in the art and, as such, are not shown in FIG. 1 and FIGS. 2A-2J. The images in FIGS. 2A-2J are not depicted to scale and are simplified for illustrative purposes.

The method 100 starts at step 101 and proceeds to step 102, when a film stack 202 is formed on a wafer 200, e.g., a silicon (Si) wafer (FIG. 2A).

The film stack 210 comprises an aluminum layer 204 and a dielectric layer 202. The aluminum layer 204 is generally formed to a thickness of between 2500 and 8000 Angstroms, while in one illustrative embodiment a thickness of the layer 204 is about 3500 Angstroms. The dielectric layer 202 is illustratively formed from silicon dioxide (SiO₂) to a thickness of about 1000 Angstroms. Examples of other dielectric materials include carbon doped silicon oxide, organic polymers, hafnium dioxide (HfO₂), alumina (Al₂O₃), and the like. In an alternative embodiment, the dielectric layer 202 may also comprise a barrier layer (not shown) of, e.g., a titanium nitride (TiN) film. In a further alternative embodiment, another similar barrier layer (not shown) may be deposited on the aluminum layer 204.

The layers 202 and 204 may be provided using a vacuum deposition technique, such as a physical vapor deposition (PVD), a chemical vapor deposition (CVD), plasma enhanced CVD (PECVD), evaporation, and the like.

The film stack 210 illustratively represents a wiring layer of an IC device that is being fabricated using the method 100. The wafer 200 may further comprise at least one other wiring layer (not shown), which may be considered, with respect to the film stack 210, as an underlying wiring layer, as well as other intermediate films or layers formed between the film stack 210 and such underlying layer.

At step 104, an α-carbon layer 206 is applied upon the aluminum layer 204 (FIG. 2B). The α-carbon material is a high-temperature inorganic carbon material, commonly referred to in the art as amorphous carbon. The α-carbon layer 206 is generally formed to a thickness in a range between 500 and 3000 Angstroms using, e.g., a PECVD process. In other embodiments and applications of the present invention, the α-carbon layer 206 may have a thickness between 200 and 5000 Angstroms. Further, the α-carbon layer 206 may be doped with nitrogen (N₂). Such doping generally improves the etch selectivity of the α-carbon material versus the materials used in the film stack 210. In one illustrative embodiment, the α-carbon layer 206 is formed to a thickness of about 1500 Angstroms. Suitable α-carbon deposition techniques are described, e.g., in commonly assigned U.S. patent application Ser. No. 09/590,322, filed Jun. 8, 2000 (Attorney docket number 4227), which is herein incorporated by reference.

At step 105, a cap layer 207 of silicon oxynitride (SiON) is formed on the α-carbon layer 206 using, e.g., a conventional CVD process (FIG. 2C). Generally, the cap layer 207 has a tuned thickness ranging from about 100 to 350 Angstroms. As a structure size is reduced, inaccuracies in a pattern transfer process can arise from optical limitations inherent to a lithographic process, such as the light reflection. In general terms, the cap layer 207 performs as an anti-reflective coating (ARC) that controls a reflection of light during patterning the photoresist (discussed in reference to step 108 below). Processes for applying a tuned combination of the α-carbon layer 206 and cap layer 207 are available from Applied Materials, Inc. of Santa Clara, Calif. under the trade name Advanced Patterning Film™ (APF).

At step 106, a photoresist layer 208 is formed on the cap layer 207 (FIG. 2D). In one illustrative embodiment, the photoresist layer 208 is applied using a conventional spin-on application procedure to a thickness of about 3000 Angstroms.

At step 108, the photoresist layer 208 is processed using a conventional lithographic patterning process. During the patterning process, the photoresist layer 208 is exposed through a patterned mask and developed, while an undeveloped portion of the photoresist is removed (FIG. 2E). A remaining developed photoresist is generally a polymer that forms a photoresist mask 212. The photoresist mask 212 rests over the α-carbon layer 206 in the region 221. The region 221 is centrally located within and wider than the region 222 that defines location and topographic dimensions (e.g., a width) of the conductive line 216 (discussed in reference to step 116 below) being formed using the method 100. Due to limitations of the lithographic patterning process, critical dimensions of the photoresist mask 212 may be accurately defined in a range of 130 nm and greater and, as such, a width 223 of the photoresist mask 212 should be reduced.

At optional step 109, the width 223 of the photoresist mask 212 is reduced to a desired width 225 (e.g., about 90 nm) using a photoresist mask trimming process (FIG. 2F). If the width of photoresist does not have to be reduced, step 109 can be skipped. The trimming process is a plasma process that performs isotropic etching of the photoresist using an oxygen (O₂) based chemistry or, alternatively, a chlorine (Cl₂) based chemistry. One such trimming process is described in commonly assigned U.S. patent application Ser. No. 10/338,251, filed Jan. 6, 2003, which is herein incorporated by reference.

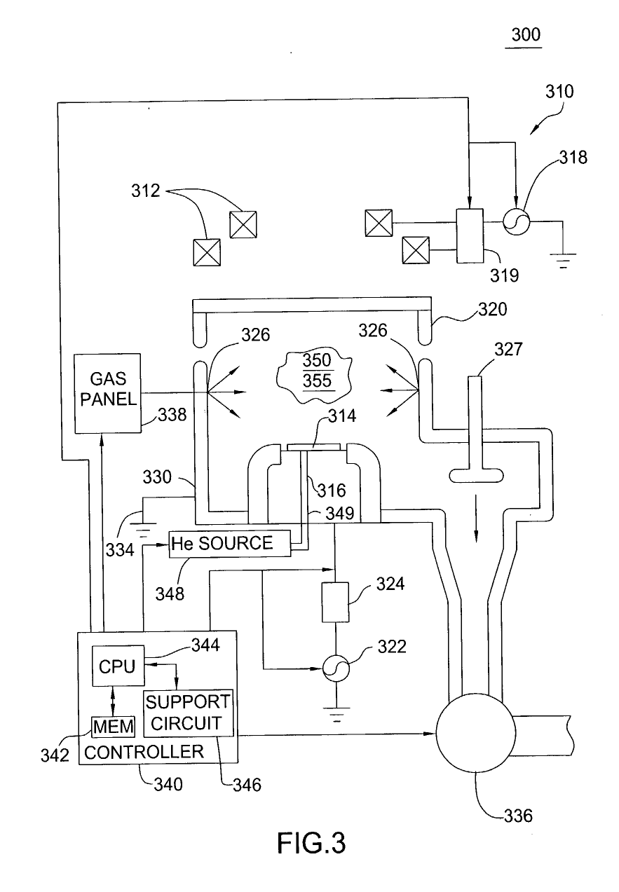

The photoresist mask trimming process can be performed, e.g., in a Decoupled Plasma Source (DPS) II reactor of the CENTURA® semiconductor wafer processing system available from Applied Materials, Inc. of Santa Clara, Calif. The DPS II reactor is described in detail in reference to FIG. 3 below. In one embodiment, the DPS 11 reactor uses an inductive plasma source to produce a high density plasma, while the wafer is biased by a source of bias power. The DPS II reactor allows an independent control of ion energy and plasma density, has a wide process window over changes in the plasma source and bias power, pressure, and gas chemistries, and may use an endpoint detection system to determine an end of the etch process.

After step 109, the trimmed photoresist mask 212 is positioned on the aluminum layer 204 in the region 222 that defines location and topographic dimensions of the α-carbon mask 214 (discussed in reference to step 110 below). After the trimming process, a height of the photoresist mask 212 also decreases, as shown in FIG. 2F.

The photoresist mask trimming process is generally used when resolution of the lithographic patterning process is insufficient for transferring an accurate image of the conductive line into the layer 208. However, in certain applications, during step 108, the photoresist mask 212 can be formed to the width 225 and, as such, step 109 may be considered optional.

At step 110, an α-carbon etch mask 214 is formed and the photoresist mask 212 is contemporaneously removed using a plasma etch process (FIG. 2G-2H). The α-carbon layer 206 and cap layer 207 are removed in the regions 220 and 224 and the cap layer 207 is generally also removed in the region 220, while the remaining portion of the layer 206 forms the α-carbon etch mask 214 in the region 222. The α-carbon etch mask 214 defines location and topographic dimensions of the aluminum conductive line 216 being formed using the method 100 (discussed in reference to step 116 below). In one embodiment, step 110 comprises a first period 112 when the α-carbon etch mask 214 is formed, and a second period 114 when the photoresist mask 212 and the cap layer 207 are entirely removed, or stripped.

During the first period 112, the etch process of step 110 forms the α-carbon etch mask 214, as well as etches (i.e., reduces a height) the photoresist mask 212 (FIG. 2G). In one embodiment, the first period 112 uses the aluminum layer 204 as an etch stop layer, e.g., an endpoint detection system of the etch reactor may monitor plasma emissions at a particular wavelength to determine that the α-carbon layer 206 has been removed in the regions 220 and 224. After the first period 112, a portion of the photoresist mask 212 (as shown in FIG. 2G) or cap layer 207 may remain on the formed α-carbon etch mask 214.

During the second period 114, the etch process of step 110 continues until the photoresist mask 212 and the cap layer 207 are entirely stripped from the α-carbon etch mask 214 (FIG. 2H). In one embodiment, the second period 114 uses the α-carbon etch mask 214 as an etch stop layer.

Those skilled in the art will appreciate that initial thickness of the photoresist mask 212 (i.e., thickness of the mask 212 prior to step 110) may be adjusted to minimize or entirely avoid overetching the aluminum layer 204 during the second period 114. Further, the initial thickness of the photoresist mask 212 may be adjusted such that the α-carbon etch mask 214 is formed and the photoresist mask 212 is removed contemporaneously. In this embodiment, the first period 112 and the second period 114 are combined together.

In one embodiment, step 110 uses an etchant gas (or gas mixture) comprising oxygen and chlorine (Cl₂), as well as a diluent gas such as argon. Alternatively, the etchant gas may comprise oxygen and nitrogen. Herein the terms “gas” and “gas mixture” are used interchangeably. In other embodiments, the etchant gas may further comprise at least one additive gas such as trifluoromethane (CHF₃), carbon tetrafluoride (CF₄), ethene (C₂H₄), and hydrogen chloride (HCl). Such etch process provides relative selectivity to α-carbon over the photoresist of about (0.4-0.7):1 and to α-carbon over aluminum of about 0.1:1, respectively.

The etch process of step 110 also facilitates self-cleaning of internal components of the process chamber from solidified residue and by-products of the etch process that are developed while etching the photoresist and α-carbon materials. Plasma of the etchant gas transforms such solidified accumulations into volatile gaseous compounds that are pump evacuated from the process chamber. As such, upon completion of step 110, the process chamber is ready for performing the next process of the method 100 upon the same wafer (i.e., in-situ) or, alternatively, for performing step 110 upon another wafer.

In an exemplary embodiment, when the DPS II reactor is used to form the α-carbon mask 214 and remove the photoresist mask 212, step 110 provides oxygen at a rate of 10 to 200 sccm and chlorine at a rate of 10 to 200 sccm (i.e., an O₂:Cl₂ flow ratio ranging from 1:20 to 20:1), as well as carbon tetrafluoride at a rate of 5 to 100 sccm and nitrogen at a rate of 5 to 100 sccm. Further, step 110 applies 500 to 3000 W of plasma power and 0 to 300 W of bias power, while maintaining a wafer temperature at 0 to 50 degrees Celsius and a pressure in the process chamber at 4 to 30 mTorr. One specific etch process provides O₂ at a rate of 30 sccm and Cl₂ at a rate of 90 sccm (i.e., an O₂:Cl₂ flow ratio of about 1:3), CF₄ at a rate of 10 sccm, N₂ at a rate of 10 sccm, 1400 W of plasma power and 150 W of bias power, a wafer temperature of 40 degrees Celsius, and a pressure of 10 mTorr.

Alternatively, step 110 can be performed in the AXIOM® reactor of the CENTURA® system. The AXIOM® reactor is described in U.S. patent application Ser. No. 10/264,664, filed Oct. 4, 2002, which is herein incorporated by reference.

The AXIOM® reactor is a remote plasma reactor in which the radio-frequency plasma is confined such that only reactive neutrals are allowed to enter a reaction volume of the process chamber. Such confinement scheme precludes plasma-related damage of the substrate or circuits formed on the substrate. In the AXIOM® reactor, a wafer backside may be heated radiantly by quartz halogen lamps or cooled using the backside gas, such that the wafer temperature can be maintained at 20 to 450 degrees Celsius. Similar to the referred to above DPS II reactor, the AXIOM® reactor may use an endpoint detection system.

At step 116, the aluminum layer 206 is removed in the regions 220 and 224, and an aluminum conductive line 216 is formed in the region 222 (FIG. 21). Step 116 may use the silicon dioxide layer 202 as an etch stop layer. In one embodiment, step 116 performs a plasma etch process that uses conventional etching chemistry, e.g., an etchant gas comprising chlorine and boron chloride (BCl₃), and a passivation gas comprising at least one of nitrogen, trifluoromethane, and ethane. During step 116, the etching chemistry and other parameters of the etch process (e.g., Cl₂: BCl₃ ratio, gas pressure in the reaction chamber, bias power, and the like) are adjusted to increase selectivity (i.e., relative etch rate) of the etch process to aluminum with respect to the inorganic amorphous carbon material of the etch mask.214.

Step 116 can be performed using, e.g., the referred to above DPS II reactor. In one illustrative embodiment, step 116 provides chlorine at a rate 50 to 300 sccm and boron chloride at a rate 30 to 300 sccm (i.e., a Cl₂:BCl₃ flow ratio ranging from 1:6 to 10:1), as well as trifluoromethane at a rate of 0 to 20 sccm. Further, step 116 applies plasma power of 400 to 1500 W at about 0.05 to 13.56 MHz, a bias power of 50 to 300 W at about 0.05 to 13.56 MHz, and maintains a wafer temperature at 0 to 50 degrees Celsius and a pressure in the reaction chamber at 4 to 40 mTorr. One exemplary process provides Cl₂ at a rate of 200 sccm and BCl₃ at a rate of 100 sccm (i.e., a Cl₂:BCl₃ flow ratio of about 2:1), CHF₃ at a rate of 5 sccm, plasma power of 600 W at 13.56 MHz, bias power of 130 W at 13.56 MHz, a wafer temperature of 40 degrees Celsius, and a pressure of 12 mTorr.

When the α-carbon etch mask 214 is used as an etch mask during step 116, such etch process provides relative selectivity to aluminum over the α-carbon material of (9-10):1 or greater (i.e., approximately 3 times better than while etching aluminum using a photoresist etch mask). As such, using the α-carbon etch masks, method 100 can form aluminum conductive lines having smaller and better controlled widths for the IC devices having high circuit density.

At step 118, the α-carbon etch mask 214 is removed (or stripped) using a plasma etch process (FIG. 2J). Step 118 may use the aluminum conductive line 216 as an etch stop layer. In one illustrative embodiment, step 118 uses an etchant gas that comprises oxygen and a diluent gas such as argon. Alternatively, a plasma comprising hydrogen may be used to remove the α-carbon etch mask 214. In one embodiment, steps 116 and 118 may be performed in a single etch reactor, e.g., the DPS II reactor.

In one exemplary embodiment, the α-carbon mask 214 is removed using the DPS II reactor. In this embodiment, step 118 provides oxygen at a rate of 5 to 100 sccm, as well as argon at a rate of 100 to 200 sccm (i.e., an O₂:Ar flow ratio ranging from 1:40 to 1:1), applies 200 to 1000 W of plasma power and 0 to 300 W of bias power, maintains a wafer temperature at 0 to 80 degrees Celsius, and a pressure in the process chamber at 2 to 30 mTorr. One etch process provides O₂ at a rate of 10 sccm and Ar at a rate of 100 sccm (i.e., an O₂:Ar flow ratio of about 1:10), 500 W of plasma power and 50 W of bias power, a wafer temperature of 50 degrees Celsius, and a pressure of 40 mTorr. In an alternative exemplary embodiment, step 118 can be performed in the AXIOM® reactor. In either embodiment, step 118 uses similar etchant gas.

Step 118 generally may be followed by optional step 119. Step 119 removes from the wafer 200 any residue and by-products developed by processes of steps 116 and 118. Step 119 generally performs a wet cleaning process using, for example, a solvent having a pH between about 3 and 12, such as EKC 265 and the like. Temperature of the EKC 265 solvent during the cleaning process typically is between 20 and 80 degrees Celsius, while a duration of the process is about 10 to 30 minutes. In one embodiment, a duration of the cleaning process using solvent EKC 265 was about 20 min at a temperature of the solvent of about 65 degrees Celsius. Solvent EKC 265 is available from EKC Technology, Inc. of Hayward, Calif. and other suppliers. After exposure to EKC 265, the wafer 200 may be rinsed in distilled water to remove any remaining traces of the solvent from the wafer. Step 119 can be performed, for example, in an automated wet cleaning module described in commonly assigned U.S. patent application Ser. No. 09/945,454, filed Aug. 31, 2001 (Attorney docket number 4936), which is herein incorporated by reference. Such wet cleaning module is available from Applied Materials, Inc. of Santa Clara, Calif.

At step 120, the method 100 ends.

FIG. 3 depicts a schematic diagram of a DPS II etch reactor 300 that may be uses to practice portions of the inventive method 100. The reactor 300 comprises a process chamber 310 having a wafer support pedestal 316 within a conductive body (wall) 330, and a controller 340.

The support pedestal (cathode) 316 is coupled, through a first matching network 324, to a biasing power source 322. The biasing source 322 generally is capable of producing up to 500 W at a frequency of approximately 13.56 MHz. In other embodiments, the source 322 may be a DC or pulsed DC source. The chamber 310 is supplied with a flat dielectric ceiling 320. Other modifications of the chamber 310 may have other types of ceilings, e.g., a dome-shaped ceiling. Above the ceiling 320 is disposed at least one inductive coil antenna 312 (two coils are shown illustratively). The antenna 312 is coupled, through a second matching network 319, to a plasma power source 318. The plasma source 318 typically is capable of producing up to 3000 W at a tunable frequency in a range from 50 kHz to 13.56 MHz. Typically, the wall 330 is coupled to an electrical ground 334.

A controller 340 comprises a central processing unit (CPU) 344, a memory 342, and support circuits 346 for the CPU 344 and facilitates control of the components of the DPS etch process chamber 310 and, as such, of the etch process, as discussed below in further detail.

In operation, a semiconductor wafer 314 is placed on the pedestal 316 and process gases are supplied from a gas panel 338 through entry ports 326 and form a gaseous mixture 350. The gaseous mixture 350 is ignited into a plasma 355 in the chamber 310 by applying power from the plasma and bias sources 318 and 322 to the antenna 312 and the cathode 316, respectively. The pressure within the interior of the chamber 310 is controlled using a throttle valve 327 and a vacuum pump 336. The temperature of the chamber wall 330 is controlled using liquid-containing conduits (not shown) that run through the wall 330.

The temperature of the wafer 314 is controlled by stabilizing a temperature of the support pedestal 316. In one embodiment, the helium gas from a gas source 348 is provided via a gas conduit 349 to channels formed by the back of the wafer 314 and grooves (not shown) in the pedestal surface. The helium gas is used to facilitate heat transfer between the pedestal 316 and the wafer 314. During the processing, the pedestal 316 may be heated by a resistive heater (not shown) within the pedestal to a steady state temperature and then the helium gas facilitates uniform heating of the wafer 314. Using such thermal control, the wafer 314 is maintained at a temperature of between 0 and 500 degrees Celsius.

Those skilled in the art will understand that other forms of etch chambers may be used to practice the invention, including chambers with remote plasma sources, microwave plasma chambers, electron cyclotron resonance (ECR) plasma chambers, and the like.

To facilitate control of the process chamber 310 as described above, the controller 340 may be one of any form of general purpose computer processor that can be used in an industrial setting for controlling various chambers and sub-processors. The memory, or computer-readable medium, 342 of the CPU 344 may be one or more of readily available memory such as random access memory (RAM), read only memory (ROM), floppy disk, hard disk, or any other form of digital storage, local or remote. The support circuits 346 are coupled to the CPU 344 for supporting the processor in a conventional manner. These circuits include cache, power supplies, clock circuits, input/output circuitry and subsystems, and the like. The inventive method is generally stored in the memory 342 as software routine. The software routine may also be stored and/or executed by a second CPU (not shown) that is remotely located from the hardware being controlled by the CPU 344.

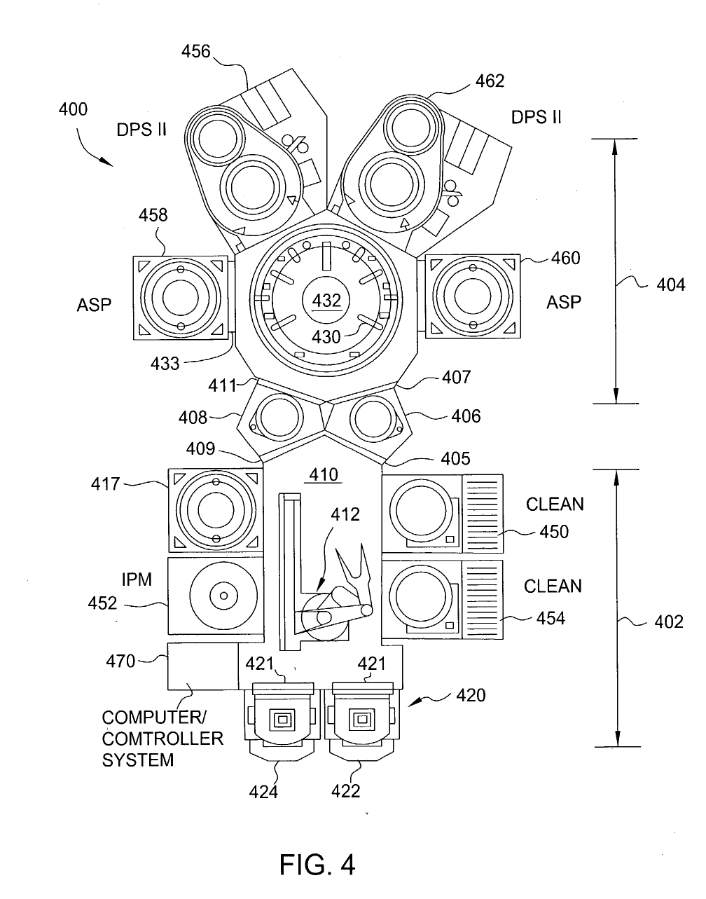

The processes of the present invention are illustratively performed, as an integrated solution for etching aluminum, on a processing platform 400 shown in FIG. 4 that comprises reactors for performing both atmospheric and sub-atmospheric processing. The platform 400 and the various modules and tools that can be used with such a platform are described in detail in U.S. patent application Ser. No. 09/945,454, filed Aug. 31, 2001 (Attorney docket number 4936), which is herein incorporated by reference. The salient features of the processing platform 400 are briefly described below.

Depending upon the process modules that are used in the platform 400, the platform 400 (also referred to as a process tool) can be used to perform etching, oxidation, substrate cleaning, photoresist stripping, substrate inspection and the like. The platform 400 comprises an atmospheric platform 402 and a sub-atmospheric platform 404. The sub-atmospheric platform 404 and the atmospheric platform 402 may be coupled together by a single substrate load lock 406 or, as shown in the depicted example, are coupled together by a pair of single load locks 406 and 408. In some applications, the sub-atmospheric and atmospheric platforms 404 and 402 are not coupled together and may be used separately. In one configuration, the stand-alone platform 402 may contain photoresist stripping reactors and wet cleaning modules that perform post-etch processing.

The atmospheric platform 402 comprises a central atmospheric transfer chamber 410 containing a substrate handling device 412, such as a robot. Directly attached to the atmospheric transfer chamber 410 is a substrate wet cleaning module 450, an integrated particle monitor 452 and a critical dimension (CD) measuring tool 454, and a photoresist stripping chamber 417. A dry clean module (not shown) can also be attached to the atmospheric transfer chamber 410, if desired. Each module or tool is coupled to the transfer chamber 410 by a separately closable and sealable opening, such as a slit valve. The transfer chamber is maintained at substantially atmospheric pressure during operation. The substrate handling device 412 is able to transfer substrates from one module or tool to another module or tool that is attached to the atmospheric transfer chamber 410. In the embodiment shown, the substrate handling device 412 is a dual blade, single arm, single wrist robot. Other types of robots may be used to access the various modules and tools.

The atmospheric transfer chamber 410 is coupled to at least one substrate input/output module 420 that provides and receives substrates to and from the platform 400. In one embodiment of the platform 400, the module 420 comprises at least one front opening unified pod (FOUP). Two FOUPs 422 and 424 are depicted. The substrate handling device 412 accesses each FOUP through a sealable access door 421. The substrate handling device 412 moves linearly along a track 423 to facilitate access to all of the modules and tools.

The atmospheric transfer chamber 410 is coupled to the pair of load locks 406 and 408 through sealable doors 405 and 409 such that the substrate handling device 412 can access the load locks 406 and 408. The sub-atmospheric platform 404 comprises a central sub-atmospheric transfer chamber 430 and a plurality of process chambers 456, 458, 460, and 462. Sealable doors 407 and 411 respectively couple each load lock 406 and 408 to the sub-atmospheric transfer chamber 430. The sub-atmospheric transfer chamber 430 contains a substrate handing device 432, such as a robot (not shown), that accesses the load locks 406 and 408 as well as the process chambers 456, 458, 460 and 462. The process chambers 456, 458, 460 and 462 are each coupled to the sub-atmospheric transfer chamber 430 via separately closable and sealable openings, such as slit-valves. The process chambers 456, 458, 460 and 462 may comprise one or more etching chambers such as the DPS or DPS II chamber. Additionally, one or more photoresist stripping chambers such as the AXIOM® chamber described above may be used as one or more of the process chambers 456, 458, 460 and 462. As also described above, the AXIOM® chamber, if used, may be located either on the sub-atmospheric platform 404 or the atmospheric platform 402. FIG. 4 shows the sub-atmospheric platform 404 comprising two DPS II chambers 456 and 462 and two AXIOM® chambers 458 and 460. The sub-atmospheric platform 404 is, for example, a CENTURA® platform available from Applied Materials, Inc. of Santa Clara, Calif.

The platform 400 also includes a system computer 470 that is coupled to and controls each module that is coupled to the atmospheric and sub-atmospheric platforms 402 and 404, controls the substrate handling devices 412 and 432, and controls the load locks 406 and 408. Generally, the system computer 470 controls all aspects of operation of the platform 400 either by direct control of the sub-systems, modules, tools and apparatus or by controlling the computers associated with those sub-systems, modules, tools and apparatus. The system computer 470 enables feedback from one module or tool to be used to control the flow of substrates through the platform 400 and/or control the processes or operation of the various modules and tools to optimize substrate throughput.

The invention may be practiced in other semiconductor structures and devices wherein the processing parameters may be adjusted to achieve acceptable characteristics by those skilled in the arts by utilizing the teachings disclosed herein without departing from the spirit of the invention.

While foregoing is directed to the illustrative embodiment of the present invention, other and further embodiments of the invention may be devised without departing from the basic scope thereof, and the scope thereof is determined by the claims that follow.

1. A method of etching a structure in an aluminum layer formed on a semiconductor substrate, comprising:
(a) forming a patterned α-carbon mask on the aluminum layer, said mask having a cap layer of SION and defining the structure by forming protected portions of the aluminum layer and unprotected portions of the aluminum layer,
(b) plasma etching the unprotected portions of the aluminum layer; and
(c) stripping the α-carbon mask.

2. The method of claim 1 wherein the α-carbon mask has a thickness in a range between 200 and 5000 Angstroms.

3. The method of claim 1 wherein the cap layer has a thickness in a range between 100 and 350 Angstroms.

4. The method of claim 1 wherein step (a) further comprises:
(a1) forming a photoresist mask exposing portion of the cap layer;
(a2) etching exposed portions of the cap layer and an underlying α-carbon layer using a plasma comprising O₂ to form the α-carbon mask; and
(a3) removing the photoresist mask.

5. The method of claim 4 wherein step (a1) further comprises:
trimming isotropically the photoresist mask using a gas comprising at least one of O₂ or Cl₂.

6. The method of claim 4 wherein the steps (a2) and (a3) are performed contemporaneously.

7. The method of claim 4 wherein the steps (a2) and (a3) further comprise:
providing O₂ and at least one of Cl₂, N₂, CHF₃, CF4, C₂H₄, and HCl.

8. The method of claim 7 wherein the steps (a2) and (a3) further comprise:
providing O₂ and Cl₂ at a flow ratio O₂:Cl₂ in a range from 1:20 to 20:1.

9. The method of claim 1 wherein the step (b) further comprises:
providing Cl₂ and BCl₃ at a flow ratio Cl₂:BCl₃ in a range from 1:6 to 10:1;
providing CHF₃ at a flow rate between 0 and 20 sccm;
maintaining a chamber pressure between 4 and 40 mTorr;
applying between 400 to 1500 W of plasma power at about 0.05 to 13.56 MHz;
applying between 50 to 300 W of substrate bias power at about 0.05 to 13.56 MHz; and
maintaining a substrate temperature between 0 to 50 degrees Celsius.

10. The method of claim 1 wherein the step (c) further comprises:
providing O₂ and Ar at a flow ratio O₂:Ar in a range from 1:40 to 1:1.

11. The method of claim 1 wherein the steps (b) and (c) are performed in a single reactor.

12. A computer-readable medium including software that, when executed by a processor, performs a method that causes a reactor to etch a structure in an aluminum layer formed on a semiconductor substrate, comprising:
(a) forming a patterned α-carbon mask on the aluminum layer, said mask having a cap layer of SiON and defining the structure by forming protected portions of the aluminum layer and unprotected portions of the aluminum layer;
(b) plasma etching the unprotected portions of the aluminum layer; and
(c) stripping the α-carbon mask.

13. The computer-readable medium of claim 12 wherein the α-carbon mask has a thickness in a range between 200 and 5000 Angstroms.

14. The computer-readable medium of claim 12 wherein the cap layer has a thickness in a range between 100 and 350 Angstroms.

15. The computer-readable medium of claim 12 wherein step (a) further comprises:
(a1) foaming a photoresist mask exposing portion of the cap layer;
(a2) etching exposed portions of the cap layer and an underlying α-carbon layer using a plasma comprising O₂ to form the α-carbon mask; and
(a3) removing the photoresist mask.

16. The computer-readable medium of claim 15 wherein step (a1) further comprises:
trimming isotropically the photoresist mask using a gas comprising at least one of O₂ or Cl₂.

17. The computer-readable medium of claim 15 wherein the steps (a2) and (a3) are performed contemporaneously.

18. The computer-readable medium of claim 15 wherein the steps (a2) and (a3) further comprise:
providing O₂ and at least one of Cl₂, N₂, CHF₃. CF4, C₂H₄, and HCl.

19. The computer-readable medium of claim 18 wherein the steps (a2) and (a3) further comprise:
providing O₂ and Cl₂ at a flow ratio O₂:Cl₂ in a range from 1:20 to 20:1.

20. The computer-readable medium of claim 12 wherein the step (b) further comprises:
providing Cl₂ and BCl₃ at a flow ratio Cl₂:BCl₃ in a range from 1:6 to 10:1;
providing CHF₃ at a flow rate between 0 and 20 sccm;
maintaining a chamber pressure between 4 and 40 mTorr;
applying between 400 to 1500 W of plasma power at about 0.05 to 13.56 MHz;
applying between 50 to 300 W of substrate bias power at about 0.05 to 13.56 MHz; and
maintaining a substrate temperature between 0 to 50 degrees Celsius.

21. The computer-readable medium of claim 12 wherein the step (c) further comprises:
providing O₂ and Ar at a flow ratio O₂:Ar in a range from 1:40 to 1:1.

22. The computer-readable medium of claim 12 wherein the steps (b) and (c) are performed in a single reactor.

23. A method of etching a structure in a metal layer formed on a semiconductor substrate, comprising:
(a) forming a patterned mask on a metal layer, said mask having α-carbon layer disposed on the metal layer and a cap layer of SiON disposed on the cap layer;
(b) plasma etching portions of the metal layer exposed through the patterned mask; and
(c) stripping the mask.

24. The method of claim 23 wherein step (a) further comprises:
(a1) forming a photoresist mask exposing portion of the cap layer;
(a2) etching exposed portions of the cap layer and an underlying α-carbon layer using a plasma comprising O₂ to pattern the mask; and
(a3) removing the photoresist mask.

25. The method of claim 24 wherein step (a1) further comprises:
trimming isotropically the photoresist mask using a gas comprising at least one of O₂ or Cl₂.

26. The method of claim 24 wherein the steps (b) and (c) are performed in a single reactor.
